(19) United States
(12) Patent Application Publication
(10) Pub. No.: US 2025/0075305 A1
(43) Pub. Date: Mar. 6, 2025

(54) METHOD FOR MANUFACTURING DEPOSITION MASK

(71) Applicant: Samsung Display Co., LTD., Yongin-si (KR)

(72) Inventors: Jin Woo LEE, Yongin-si (KR); Jeong Kuk KIM, Yongin-si (KR); Duck Jung LEE, Yongin-si (KR); Sug Woo JUNG, Yongin-si (KR); Sung Won CHO, Yongin-si (KR); Jun Ho JO, Yongin-si (KR)

(21) Appl. No.: 18/642,578

(22) Filed: Apr. 22, 2024

(30) Foreign Application Priority Data
Aug. 30, 2023 (KR) 10-2023-0114409

(51) Int. Cl. C23C 14/04; H10K 71/16

(52) U.S. Cl. CPC C23C 14/042; H10K 71/166

(57) ABSTRACT

A method for manufacturing a deposition mask includes depositing a seed metal layer on a front surface of a silicon substrate, forming a first photoresist pattern defining first openings on the seed metal layer, growing a plating layer in the first openings of the first photoresist pattern, forming a mask membrane by removing the first photoresist pattern and leaving the plating layer, depositing a protection layer to cover a front surface of the mask membrane, forming a second photoresist pattern defining cell opening corresponding to unit masks, respectively, on a back surface of the silicon substrate, exposing the seed metal layer by etching the back surface of the silicon substrate using the second photoresist pattern as a mask, exposing a back surface of the mask membrane by etching the seed metal layer using the second photoresist pattern as a mask, and removing the protection layer.

This application claims priority to Korean Patent Application No. 10-2023-0114409, filed on Aug. 30, 2023, and all the benefits accruing therefrom under 35 U.S.C. § 119, the content of which in its entirety is herein incorporated by reference.

### BACKGROUND

### 1. Field

Embodiments of the disclosure relates to a method for manufacturing a deposition mask.

### 2. Description of the Related Art

A wearable device that forms a focus at a short distance from a user's eyes is being developed in the form of glasses or a helmet. For example, the wearable device may be a head mounted display (HMD) device or augmented reality (AR) glasses. Such a wearable device provides an AR screen or a virtual reality (VR) screen to a user.

A wearable device such as an HMD device or AR glasses may be desired to have a display specification of at least 2000 pixels per inch (PPI) to allow a user to use it for a long time without dizziness. To implement a wearable device, organic light emitting diode on silicon (OLEDoS) technology, which is a small high-resolution organic light emitting display device, is being proposed. OLEDoS is a technology for placing an organic light emitting diode (OLED) on a semiconductor wafer substrate on which a complementary metal oxide semiconductor (CMOS) is disposed.

### SUMMARY

Embodiments of the disclosure provide a method for manufacturing a deposition mask with improved reliability by improving pixel position accuracy (PPA).

Embodiments of the disclosure also provide a method for manufacturing a deposition mask that can increase an alignment accuracy of the mask and prevent mura defects caused by the sagging of the mask by applying mask grids (or mask ribs) to which a magnetic metal is applied to prevent the mask from sagging.

According to an embodiment of the disclosure, a method for manufacturing a deposition mask includes depositing a seed metal layer on a front surface of a silicon substrate, forming a first photoresist pattern defining a plurality of first openings on the seed metal layer, growing a plating layer in the plurality of first openings of the first photoresist pattern, forming a mask membrane by removing the first photoresist pattern and leaving the plating layer, depositing a protection layer on a front surface of the seed metal layer to cover a front surface of the mask membrane, forming a second photoresist pattern defining a plurality of cell opening corresponding to a plurality of unit masks, respectively, on a back surface of the silicon substrate, exposing the seed metal layer by etching the back surface of the silicon substrate using the second photoresist pattern as a mask, exposing a back surface of the mask membrane by etching the seed metal layer using the second photoresist pattern as a mask, and removing the protection layer.

In an embodiment, the seed metal layer may include a first metal layer including titanium (Ti) and a second metal layer disposed on the first metal layer and including titanium nitride (TiN).

In an embodiment, the seed metal layer may include a single metal layer including titanium (Ti).

In an embodiment, the seed metal layer may include a single metal layer including titanium nitride (TiN).

In an embodiment, the mask membrane may include a mask grid formed by the plating layer, where a mask opening may be defined between adjacently disposed mask grids to correspond to an area where the first photoresist pattern is removed.

In an embodiment, a cross-section of the mask grid may have a reverse tapered shape having a width increasing as being away from the back surface of the mask membrane toward the front surface of the mask membrane.

In an embodiment, the mask opening may have a width decreasing as being away from the back surface of the mask membrane to the front surface of the mask membrane.

In an embodiment, an opening of the mask may have a first width at the back surface of the mask membrane and a second width smaller than the first width at the front surface of the mask membrane.

In an embodiment, the plating layer may include tungsten (W).

In an embodiment, the plating layer may include copper (Cu).

According to an embodiment of the disclosure, a method for manufacturing a deposition mask includes forming an inorganic layer pattern defining a plurality of first openings on a front surface of a silicon substrate, depositing a seed metal layer on the front surface of the silicon substrate to cover the inorganic layer pattern and the plurality of first openings, growing a plating layer on the seed metal layer in a way such that that a height of the plating layer becomes higher than a height of the inorganic layer pattern, polishing a portion of the seed metal layer and a portion of the plating layer disposed on the inorganic layer pattern by performing chemical mechanical polishing pad (CMP) process, depositing a protection layer on the inorganic layer pattern, forming a photoresist pattern defining a plurality of cell opening corresponding to a plurality of unit masks, respectively, on a back surface of the silicon substrate, exposing the seed metal layer and the inorganic layer pattern by etching the back surface of the silicon substrate using the photoresist pattern as a mask, and forming a mask membrane by removing the inorganic layer pattern and the protection layer, The mask membrane may include a mask grid including the plating layer and the seed metal layer covering the plating layer.

In an embodiment, the seed metal layer may include a first metal layer including titanium (Ti) and a second metal layer disposed on the first metal layer and including titanium nitride (TiN).

In an embodiment, the seed metal layer may include a single metal layer including titanium (Ti).

In an embodiment, the seed metal layer may include a single metal layer including titanium nitride (TiN).

In an embodiment, the mask membrane may include a mask grid including the plating layer and the seed metal layer covering the plating layer, where a mask opening may be defined between adjacently disposed mask grids to correspond to an area where the inorganic layer pattern is removed.

In an embodiment, the cross-section of the mask grid may have a reverse tapered shape having a width increasing as being away from the back surface of the mask membrane toward the front surface of the mask membrane.

In an embodiment, the mask opening may have a width decreasing as being away from the back surface of the mask membrane to the front surface of the mask membrane.

In an embodiment, the opening of the mask may have a first width at the back surface of the mask membrane and a second width smaller than the first width at the top surface of the mask membrane.

In an embodiment, the plating layer may include tungsten (W).

In an embodiment, the plating layer may include copper (Cu).

However, aspects of the disclosure are not restricted to the one set forth herein. The above and other aspects of the disclosure will become more apparent to one of ordinary skill in the art to which the disclosure pertains by referencing the detailed description of the disclosure given below.

A method for manufacturing a deposition mask according to embodiments can improve reliability by improving pixel position accuracy (PPA).

In addition, the method for manufacturing a deposition mask according to embodiments prevent the mask from sagging by applying mask grids (or mask ribs) to which a magnetic metal is applied. Accordingly, the alignment accuracy of the mask can be increased, and mura defects caused by the sagging of the mask can be effectively prevented.

In addition, the method for manufacturing a deposition mask according to embodiments has improved rigidity or durability of the mask, thereby increasing the number of times the mask is used.

However, the effects of embodiments of the disclosure are not restricted to the one set forth herein. The above and other effects of embodiments of the disclosure will become more apparent to one of daily skill in the art to which the disclosure pertains by referencing the claims.

### BRIEF DESCRIPTION OF THE DRAWINGS

The above and other features of embodiments of the disclosure will become more apparent by describing detailed embodiments thereof with reference to the accompanying drawings, in which:

FIG. 1 is a perspective view of a head mounted display device according to an embodiment;

FIG. 2 is an exploded perspective view of an example of the head mounted display device of FIG. 1;

FIG. 3 is a perspective view of a head mounted display device according to an embodiment;

FIG. 4 is an exploded perspective view of a display device according to an embodiment;

FIG. 5 is a cross-sectional view of an example of a part of a display panel according to an embodiment;

FIG. 6 is a perspective view of a mask according to an embodiment;

FIG. 7 is a schematic cross-sectional view of a mask according to an embodiment;

FIGS. 8 to 16 are cross-sectional view for explaining a method for manufacturing a mask according to an embodiment illustrated in FIG. 7;

FIG. 17 is a schematic cross-sectional view of a mask according to an embodiment; and

FIGS. 18 to 25 are cross-sectional views for explaining a method for manufacturing a mask according to an embodiment illustrated in FIG. 17.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Features of each of various embodiments of the disclosure may be partially or entirely combined with each other and may technically variously interwork with each other, and respective embodiments may be implemented independently of each other or may be implemented together in association with each other.

Hereinafter, embodiments of the disclosure will be described in detail with reference to the accompanying drawings.

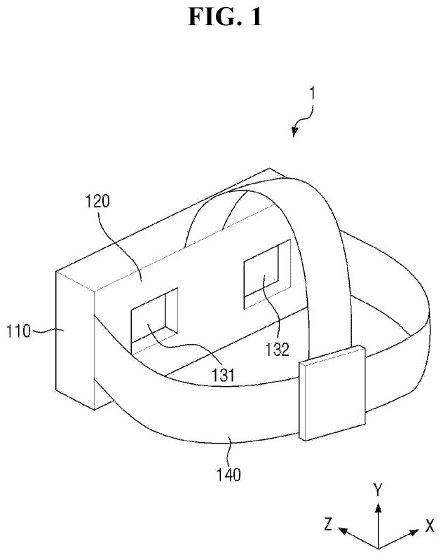

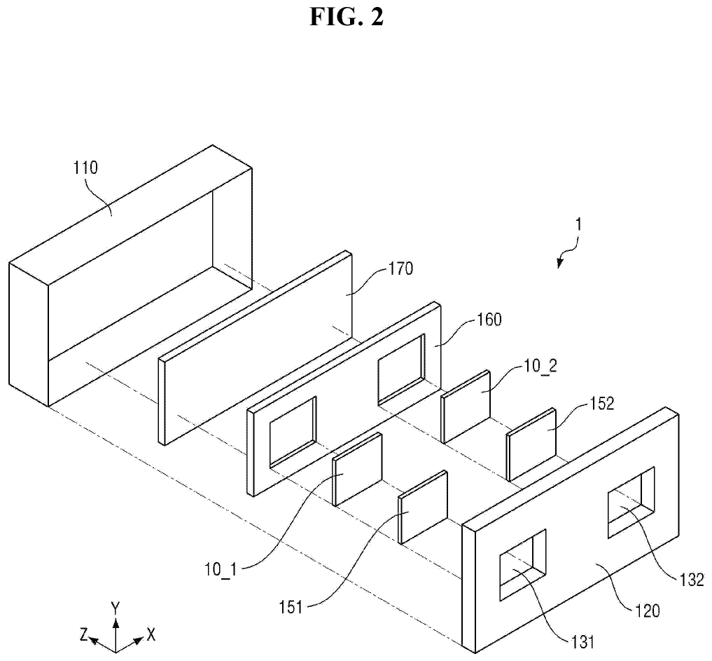

FIG. 1 is a perspective view of a head mounted display device according to an embodiment. FIG. 2 is an exploded perspective view of an example of the head mounted display device of FIG. 1.

Referring to FIGS. 1 and 2, a head mounted display device 1 according to an embodiment includes a first display device 10_1, a second display device 10_2, a display device housing 110, a housing cover 120, a first eyepiece 131, a second eyepiece 132, a head mounted band 140, a middle frame 160, a first optical member 151, a second optical member 152, a control circuit board 170, and a connector.

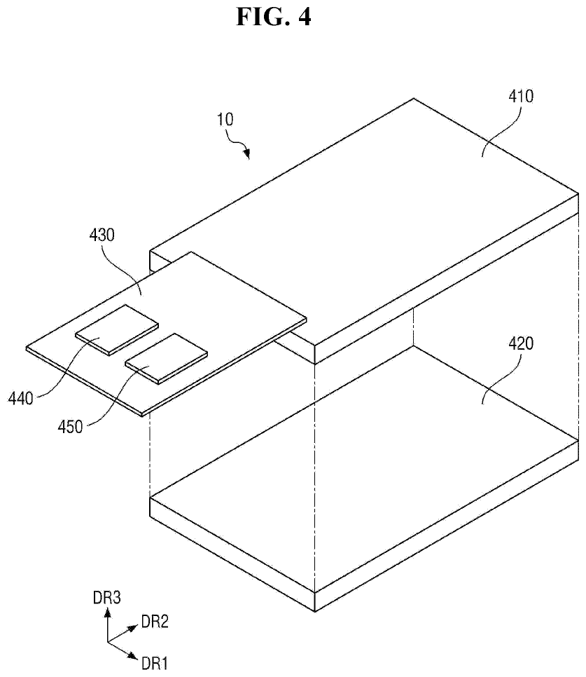

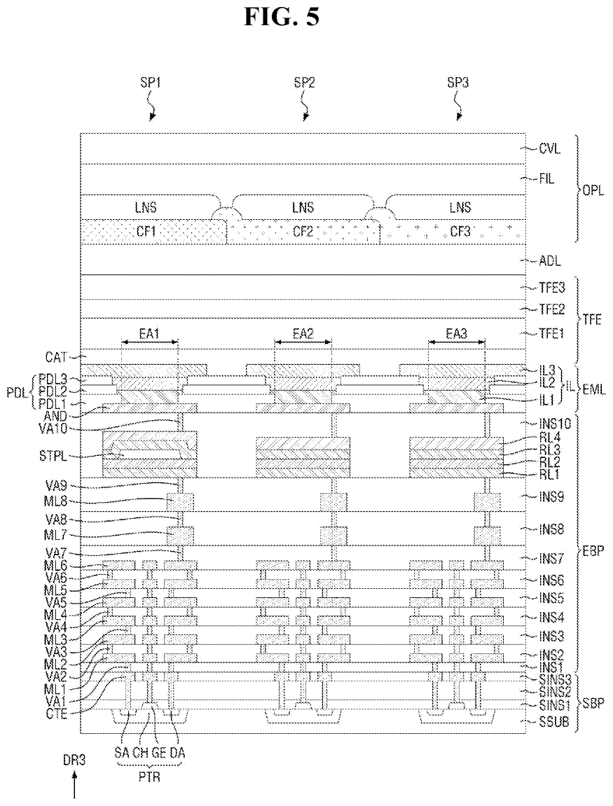

The first display device 10_1 provides an image to a user's left eye, and the second display device 10_2 provides an image to the user's right eye. Each of the first display device 10_1 and the second display device 10_2 is substantially the same as a display device 10 to be described with reference to FIGS. 4 and 5. Therefore, a description of the first display device 10_1 and the second display device 10_2 will be replaced with descriptions given with reference to FIGS. 4 and 5.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 supports and fixes the first display device 10_1, the second display device 10_2, and the control circuit board 170.

The control circuit board 170 may be disposed between the middle frame 160 and the display device housing 110. The control circuit board 170 may be connected to the first display device 10_1 and the second display device 10_2 through the connector. The control circuit board 170 may convert an image source received from the outside into digital video data and transmit the digital video data to the first display device 10_1 and the second display device 10_2 through the connector.

In an embodiment, the control circuit board 170 may transmit the digital video data corresponding to a left-eye image optimized for a user's left eye to the first display device 10_1 and transmit the digital video data corresponding to a right-eye image optimized for the user's right eye to the second display device 10_2. Alternatively, the control circuit board 170 may transmit the same digital video data to the first display device 10_1 and the second display device 10_2.

The display device housing 110 houses or accommodates the first display device 10_1, the second display device 10_2, the middle frame 160, the first optical member 151, the second optical member 152, the control circuit board 170, and the connector. The housing cover 120 is placed to cover an open surface of the display device housing 110. The housing cover 120 may include the first eyepiece 131 on which a user's left eye is placed and the second eyepiece 132 on which the user's right eye is placed. In an embodiment, the first eyepiece 131 and the second eyepiece 132 are provided or disposed separately as shown in FIGS. 1 and 2, but embodiments of the disclosure are not limited thereto. Alternatively, the first eyepiece 131 and the second eyepiece 132 may also be combined into one.

The first eyepiece 131 may be aligned with the first display device 10_1 and the first optical member 151, and the second eyepiece 132 may be aligned with the second display device 10_2 and the second optical member 152. Therefore, a user can view an image of the first display device 10_1, which is enlarged as a virtual image by the first optical member 151, through the first eyepiece 131 and can view an image of the second display device 10_2, which is enlarged as a virtual image by the second optical member 152, through the second eyepiece 132.

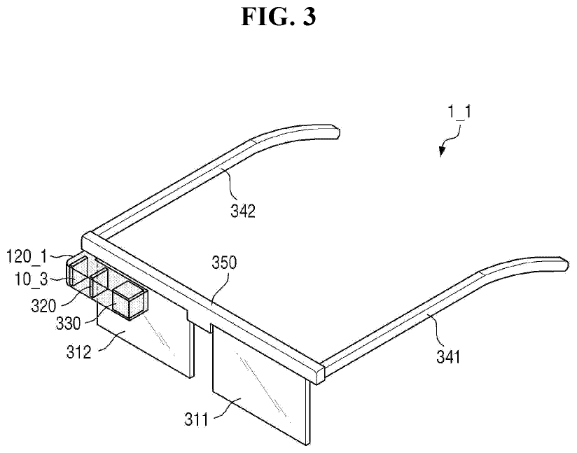

The head mounted band 140 fixes the display device housing 110 to a user's head so that the first eyepiece 131 and the second eyepiece 132 of the housing cover 120 are kept placed on the user's left and right eyes, respectively. In an embodiment where a display device housing 110 is desired to be implemented to be lightweight and small, the head mounted display device 1 may include an eyeglass frame as illustrated in FIG. 3 instead of the head mounted band 140.

In an embodiment, the head mounted display device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view of a head mounted display device according to an embodiment.

Referring to FIG. 3, a head mounted display device 1_1 according to an embodiment may be a display device in the form of glasses in which a display device housing 120_1 is implemented to be lightweight and small. The head mounted display device 1_1 according to an embodiment may include a display device 10_3, a left-eye lens 311, a right-eye lens 312, a support frame 350, eyeglass frame legs 341 and 342, an optical member 320, an optical path conversion member 330, and the display device housing 120_1.

The display device 10_3 illustrated in FIG. 3 is substantially the same as the display device 10 to be described with reference to FIGS. 4 and 5. Therefore, a description of the display device 10_3? Will be replaced with the descriptions given with reference to FIGS. 4 and 5.

The display device housing 120_1 may include the display device 10_3, the optical member 320, and the optical path conversion member 330. An image displayed on the display device 10_3 may be enlarged by the optical member 320, may have its optical path converted by the optical path conversion member 330, and then may be provided to a user's right eye through the right-eye lens 312. Accordingly, the user can view, through the right eye, an augmented reality image into which a virtual image displayed on the display device 10_3 and a real image viewed through the right-eye lens 312 are combined.

In an embodiment, the display device housing 120_1 may be disposed at a right end of the support frame 350 as shown in FIG. 3, but embodiments of the disclosure are not limited thereto. In an embodiment, for example, the display device housing 120_1 may also be disposed at a left end of the support frame 350. In such an embodiment, an image of the display device 10_3 may be provided to a user's left eye. Alternatively, the display device housing 120_1 may be disposed at both the left and right ends of the support frame 350. In such an embodiment, the user can view an image displayed on the display device 10_3 through both the left and right eyes.

FIG. 4 is an exploded perspective view of a display device according to an embodiment.

Referring to FIG. 4, the display device 10 according to an embodiment is a device for displaying moving images or still images. The display device 10 according to the embodiment may be applied to portable electronic devices such as mobile phones, smartphones, tablet personal computers (PCs), mobile communication terminals, electronic notebooks, laptop computers, electronic books, portable multimedia players (PMPs), navigation devices, and ultra-mobile PCs (UMPCs). In an embodiment, for example, the display device 10 may be applied as a display unit of a television, a notebook computer, a monitor, a billboard, or an Internet of things (IoT) device. Alternatively, the display device 10 may be applied to smart watches, watch phones, and head mounted displays for implementing virtual reality and augmented reality.

The display device 10 according to an embodiment includes a display panel 410, a heat dissipation layer 420, a circuit board 430, a driving circuit 440, and a power supply circuit 450.

The display panel 410 may have a planar shape similar to a quadrangle. In an embodiment, for example, the display panel 410 may have a planar shape similar to a quadrangle having short sides in a first direction DR1 and long sides in a second direction DR2 intersecting the first direction DR1. In the display panel 410, each corner where a short side extending in the first direction DR1 meets a long side extending in the second direction DR2 may be rounded with a predetermined curvature or may be right-angled. The planar shape of the display panel 410 is not limited to a quadrangular shape, but may also be similar to another polygonal shape, a circular shape, or an oval shape. The planar shape of the display device 10 may correspond to the planar shape of the display panel 410, but embodiments of the disclosure are not limited thereto.

The display panel 410 includes a display area that displays an image and a non-display area that does not display an image.

The display area includes a plurality of pixels, and each of the pixels includes a plurality of subpixels SP1 through SP3 (see FIG. 5). The subpixels SP1 through SP3 include a plurality of pixel transistors. The pixel transistors may be formed through a semiconductor process and may be disposed on a semiconductor substrate SSUB (see FIG. 5). In an embodiment, for example, the pixel transistors may be formed as complementary metal oxide semiconductors (CMOS).

The heat dissipation layer 420 may overlap the display panel 410 in a third direction DR3 which is a thickness direction of the display panel 410. The heat dissipation layer 420 may be disposed on a surface, e.g., a back surface of the display panel 410. The heat dissipation layer 420 dissipates heat generated in the display panel 410. The heat dissipation layer 420 may include a metal layer having high thermal conductivity, such as graphite, silver (Ag), copper (Cu), or aluminum (Al).

The circuit board 430 may be electrically connected to a plurality of pads PD in a pad area PDA of the display panel 410 by using a conductive adhesive member such as an anisotropic conductive film. The circuit board 430 may be a flexible printed circuit board including or made of a flexible material or may be a flexible film. Although the circuit board 430 in an unfolded states is shown in FIG. 4, the circuit board 430 may also be bent. In a bent state, one end of the circuit board 430 may be placed on the back surface of the display panel 410. The end of the circuit board 430 may be an end opposite the other end of the circuit board 430 which is connected to the pads PD in the pad area PDA of the display panel 410 by using the conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate a plurality of panel driving voltages according to a power supply voltage received from the outside. In an embodiment, for example, the power supply circuit 450 may generate a first driving voltage (e.g., a low driving voltage), a second driving voltage (e.g., a high driving voltage) and a third driving voltage (e.g., an initialization voltage) and supply the first to third voltages to the display panel 410.

Each of the driving circuit 440 and the power supply circuit 450 may be formed as an integrated circuit and attached to a surface of the circuit board 430.

FIG. 5 is a cross-sectional view of an example of a part of a display panel according to an embodiment. Particularly, FIG. 5 illustrates a partial cross-sectional structure of a display area including a plurality of subpixels SP1 through SP3.

Referring to FIG. 5, an embodiment of the display panel 410 includes a semiconductor backplane SBP, a light emitting element backplane EBP, a light emitting element layer EML, an encapsulation layer TFE, an optical layer OPL, a cover layer CVL, and a polarizer (not illustrated).

The semiconductor backplane SBP includes a semiconductor substrate SSUB including a plurality of pixel transistors PTR, a plurality of semiconductor insulating layers covering the pixel transistors PTR, and a plurality of contact terminals CTE electrically connected to the pixel transistors PTR.

The semiconductor substrate SSUB may be a silicon substrate, a germanium substrate, or a silicon-germanium substrate. The semiconductor substrate SSUB may be a substrate doped with first-type impurities. A plurality of well areas WA may be defined or provided on an upper surface of the semiconductor substrate SSUB. The well areas WA may be areas doped with second-type impurities. The second-type impurities may be different from the first-type impurities. In an embodiment, for example, where the first-type impurities are p-type impurities, the second-type impurities may be n-type impurities. Alternatively, in a case where the first-type impurities are n-type impurities, the second-type impurities may be p-type impurities.

Each of the well areas WA includes a source area SA corresponding to a source electrode of a pixel transistor PTR, a drain area DA corresponding to a drain electrode, and a channel area CH disposed between the source area SA and the drain area DA.

Each of the source area SA and the drain area DA may be an area doped with the first-type impurities. A gate electrode GE of each pixel transistor PTR may overlap a well area WA in the third direction DR3. The channel area CH may overlap the gate electrode GE in the third direction DR3. The source area SA may be disposed on one side of the gate electrode GE, and the drain area DA may be disposed on an opposing side of the gate electrode GE.

Each of the well areas WA further includes a first lightly doped impurity area disposed between the channel area CH and the source area SA and a second lightly doped impurity area disposed between the channel area CH and the drain area DA. The first lightly doped impurity area may be an area having a lower impurity concentration than the source area SA. The second lightly doped impurity area LDD2 may be an area having a lower impurity concentration than the drain area DA. A distance between the source area SA and the drain area DA may be increased by the first lightly doped impurity area and the second lightly doped impurity area. Accordingly, a length of the channel area CH of each pixel transistor PTR may increase, thereby effectively preventing punch-through and hot carrier phenomena caused by a short channel.

A first semiconductor insulating layer SINS1 may be disposed on the semiconductor substrate SSUB. The first semiconductor insulating layer SINS1 may be a silicon carbon nitride (SiCN) or silicon oxide (SiOx)-based inorganic layer, but embodiments of the disclosure are not limited thereto.

A second semiconductor insulating layer SINS2 may be disposed on the first semiconductor insulating layer SINS1. The second semiconductor insulating layer SINS2 may be a silicon oxide (SiOx)-based inorganic layer, but embodiments of the disclosure are not limited thereto.

The contact terminals CTE may be disposed on the second semiconductor insulating layer SINS2. Each of the contact terminals CTE may be connected to at least one selected from the gate electrode GE, the source area SA, and the drain area DA of a pixel transistor PTR through a hole formed or defined through the first semiconductor insulating layer SINS1 and the second semiconductor insulating layer SINS2. The contact terminals CTE may include or be made of at least one selected from copper (Cu), aluminum (Al), tungsten (W), molybdenum (Mo), chromium (Cr), gold (Au), titanium (Ti), nickel (Ni) and neodymium (Nd) or an alloy thereof.

A third semiconductor insulating layer SINS3 may be disposed on side surfaces of each of the contact terminals CTE. An upper surface of each of the contact terminals CTE may be exposed without being covered by the third semiconductor insulating layer SINS3. The third semiconductor insulating layer SINS3 may be a silicon oxide (SiOx)-based inorganic layer, but embodiments of the disclosure are not limited thereto.

In an embodiment, the semiconductor substrate SSUB can be replaced with a glass substrate or a polymer resin substrate such as polyimide. In such an embodiment, thin-film transistors may be disposed on the glass substrate or the polymer resin substrate. The glass substrate may be a rigid substrate that is not bendable, and the polymer resin substrate may be a flexible substrate that can be bent or curved.

The light emitting element backplane EBP includes first through eighth metal layers ML1 through ML8, reflective electrodes RL1 through RL4, a plurality of vias VA1 through VA10, and a step layer STPL. In addition, the light emitting element backplane EBP includes a plurality of interlayer insulating layers INS1 through INS10 disposed between the first through eighth metal layers ML1 through ML8.

The first through eighth metal layers ML1 through ML8 serve to implement the circuit of a first subpixel SP1 by connecting the contact terminals CTE exposed in the semiconductor backplane SBP. That is, only first through sixth transistors TI through T6 are formed in the semiconductor backplane SBP, and the connection of the first through sixth transistors TI through T6 and a first capacitor C1 and a second capacitor C2 is achieved through the first through eighth metal layers ML1 through ML8. In addition, the connection between a drain area corresponding to a drain electrode of the fourth transistor T4 and a source area corresponding to a source electrode of the fifth transistor T5 and a first electrode of a light emitting element LE is also achieved through the first through eighth metal layers ML1 through ML8.

A first interlayer insulating layer INS1 may be disposed on the semiconductor backplane SBP. First vias VA1 may penetrate or be disposed through the first interlayer insulating layer INS1 and may be respectively connected to the contact terminals CTE exposed in the semiconductor backplane SBP. The first metal layers ML1 may be disposed on the first interlayer insulating layer INS1 and may be connected to the first vias VA1, respectively.

A second interlayer insulating layer INS2 may be disposed on the first interlayer insulating layer INS1 and the first metal layers ML1. Second vias VA2 may penetrate or be disposed through the second interlayer insulating layer INS2 and may be connected to the exposed first metal layers ML1, respectively. The second metal layers ML2 may be disposed on the second interlayer insulating layer INS2 and may be connected to the second vias VA2, respectively.

A third interlayer insulating layer INS3 may be disposed on the second interlayer insulating layer INS2 and the second metal layers ML2. Third vias VA3 may penetrate or be disposed through the third interlayer insulating layer INS3 and may be connected to the exposed second metal layers ML2, respectively. The third metal layers ML3 may be disposed on the third interlayer insulating layer INS3 and may be connected to the third vias VA3, respectively.

A fourth interlayer insulating layer INS4 may be disposed on the third interlayer insulating layer INS3 and the third metal layers ML3. Fourth vias VA4 may penetrate or be disposed through the fourth interlayer insulating layer INS4 and may be connected to the exposed third metal layers ML3, respectively. The fourth metal layers ML4 may be disposed on the fourth interlayer insulating layer INS4 and may be connected to the fourth vias VA4, respectively.

A fifth interlayer insulating layer INS5 may be disposed on the fourth interlayer insulating layer INS4 and the fourth metal layers ML4. Fifth vias VA5 may penetrate or be disposed through the fifth interlayer insulating layer INS5 and may be connected to the exposed fourth metal layers ML4, respectively. The fifth metal layers ML5 may be disposed on the fifth interlayer insulating layer INS5 and may be connected to the fifth vias VA5, respectively.

A sixth interlayer insulating layer INS6 may be disposed on the fifth interlayer insulating layer INS5 and the fifth metal layers ML5. Sixth vias VA6 may penetrate or be disposed through the sixth interlayer insulating layer INS6 and may be connected to the exposed fifth metal layers ML5, respectively. The sixth metal layers ML6 may be disposed on the sixth interlayer insulating layer INS6 and may be connected to the sixth vias VA6, respectively.

A seventh interlayer insulating layer INS7 may be disposed on the sixth interlayer insulating layer INS6 and the sixth metal layers ML6. Seventh vias VA7 may penetrate or be disposed through the seventh interlayer insulating layer INS7 and may be connected to the exposed sixth metal layers ML6, respectively. The seventh metal layers ML7 may be disposed on the seventh interlayer insulating layer INS7 and may be connected to the seventh vias VA7, respectively.

An eighth interlayer insulating layer INS8 may be disposed on the seventh interlayer insulating layer INS7 and the seventh metal layers ML7. Eighth vias VA8 may penetrate or be disposed through the eighth interlayer insulating layer INS8 and may be connected to the exposed seventh metal layers ML7, respectively. The eighth metal layers ML8 may be disposed on the eighth interlayer insulating layer INS8 and may be connected to the eighth vias VA8, respectively.

The first through eighth metal layers ML1 through ML8 and the first through eighth vias VA1 through VA8 may include or be made of substantially the same material as each other. The first through eighth metal layers ML1 through ML8 and the first through eighth vias VA1 through VA8 may include or be made of at least one selected from copper (Cu), aluminum (Al), tungsten (W), molybdenum (Mo), chromium (Cr), gold (Au), titanium (Ti), nickel (Ni) and neodymium (Nd) or may be made of an alloy including any one of the same. The first through eighth vias VA1 through VA8 may include or be made of substantially the same material as each other. In an embodiment, each of the first through eighth interlayer insulating layers INS1 through INS8 may be a silicon oxide (SiOx)-based inorganic layer, but embodiments of the disclosure are not limited thereto.

A thickness of the first metal layers ML1, a thickness of the second metal layers ML2, a thickness of the third metal layers ML3, a thickness of the fourth metal layers ML4, a thickness of the fifth metal layers ML5, and a thickness of the sixth metal layers ML6 may each be greater than a thickness of the first vias VA1, a thickness of the second vias VA2, a thickness of the third vias VA3, a thickness of the fourth vias VA4, a thickness of the fifth vias VA5, and a thickness of the sixth vias VA6. The thickness of the second metal layers ML2, the thickness of the third metal layers ML3, the thickness of the fourth metal layers ML4, the thickness of the fifth metal layers ML5, and the thickness of the sixth metal layers ML6 may each be greater than the thickness of the first metal layers ML1. The thickness of the second metal layers ML2, the thickness of the third metal layers ML3, the thickness of the fourth metal layers ML4, the thickness of the fifth metal layers ML5, and the thickness of the sixth metal layers ML6 may be substantially the same as each other. In an embodiment, for example, the thickness of the first metal layers ML1 may be about 1360 angstroms (Å), the thickness of the second metal layers ML2, the thickness of the third metal layers ML3, the thickness of the fourth metal layers ML4, the thickness of the fifth metal layers ML5 and the thickness of the sixth metal layers ML6 may each be about 1440 Å, and the thickness of the first vias VA1, the thickness of the second vias VA2, the thickness of the third vias VA3, the thickness of the fourth vias VA4, the thickness of the fifth vias VA5 and the thickness of the sixth vias VA6 may each be about 1150 Å.

A thickness of the seventh metal layers ML7 and a thickness of the eighth metal layers ML8 may each be greater than the thickness of the first metal layers ML1, the thickness of the second metal layers ML2, the thickness of the third metal layers ML3, the thickness of the fourth metal layers ML4, the thickness of the fifth metal layers ML5, and the thickness of the sixth metal layer ML6. The thickness of the seventh metal layers ML7 and the thickness of the eighth metal layers ML8 may each be greater than a thickness of the seventh vias VA7 and a thickness of the eighth vias VA8. The thickness of the seventh vias VA7 and the thickness of the eighth vias VA8 may each be greater than the thickness of the first vias VA1, the thickness of the second vias VA2, the thickness of the third vias VA3, the thickness of the fourth vias VA4, the thickness of the fifth vias VA5, and the thickness of the sixth vias VA6. The thickness of the seventh metal layers ML7 and the thickness of the eighth metal layers ML8 may be substantially the same as each other. In an embodiment, for example, the thickness of the seventh metal layers ML7 and the thickness of the eighth metal layers ML8 may each be about 9000 Å. The thickness of the seventh vias VA7 and the thickness of the eighth vias VA8 may each be about 6000 Å.

A ninth interlayer insulating layer INS9 may be disposed on the eighth interlayer insulating layer INS8 and the eighth metal layers ML8. In an embodiment, the ninth interlayer insulating layer INS9 may be a silicon oxide (SiOx)-based inorganic layer, but embodiments of the disclosure are not limited thereto.

Ninth vias VA9 may penetrate the ninth interlayer insulating layer INS9 and may be connected to the exposed eighth metal layers ML8, respectively. In an embodiment, the ninth vias VA9 may include or be made of at least one selected from copper (Cu), aluminum (Al), tungsten (W), molybdenum (Mo), chromium (Cr), gold (Au), titanium (Ti), nickel (Ni) and neodymium (Nd) or an alloy thereof. In an embodiment, for example, a thickness of the ninth vias VA9 may be about 16500 Å.

First reflective electrodes RL1 may be disposed on the ninth interlayer insulating layer INS9 and may be connected to the ninth vias VA9, respectively. The first reflective electrodes RL1 may include or be made of at least one selected from copper (Cu), aluminum (Al), tungsten (W), molybdenum (Mo), chromium (Cr), gold (Au), titanium (Ti), nickel (Ni) and neodymium (Nd) or an alloy thereof.

Second reflective electrodes RL2 may be disposed on the first reflective electrodes RL1, respectively. The second reflective electrodes RL2 may include or be made of at least one selected from copper (Cu), aluminum (Al), tungsten (W), molybdenum (Mo), chromium (Cr), gold (Au), titanium (Ti), nickel (Ni) and neodymium (Nd) or an alloy thereof. In an embodiment, for example, the second reflective electrodes RL2 may be titanium nitride (TiN).

In the first subpixel SP1, the step layer STPL may be disposed on a second reflective electrode RL2. The step layer STPL may not be disposed in a second subpixel SP2 and a third subpixel SP3. A thickness of the step layer STPL may be set in consideration of the wavelength of light of a first color and a distance from a first light emitting layer EML1 to a fourth reflective electrode RL4 to facilitate the reflection of the light of the first color emitted from the first light emitting layer EML1 of the first subpixel SP1. In an embodiment, the step layer STPL may be a silicon carbon nitride (SiCN) or silicon oxide (SiOx)-based inorganic layer, but embodiments of the disclosure are not limited thereto. In an embodiment, for example, the thickness of the step layer STPL may be about 400 Å.

In the first subpixel SP1, a third reflective electrode RL3 may be disposed on the second reflective electrode RL2 and the step layer STPL. In each of the second subpixel SP2 and the third subpixel SP3, the third reflective electrode RL3 may be disposed on the second reflective electrode RL2. The third reflective electrodes RL3 may include or be made of at least one selected from copper (Cu), aluminum (Al), tungsten (W), molybdenum (Mo), chromium (Cr), gold (Au), titanium (Ti), nickel (Ni) and neodymium (Nd) or an alloy thereof.

In an embodiment, at least one selected from the first through third reflective electrodes RL1 through RL3 may be omitted.

Fourth reflective electrodes RL4 may be disposed on the third reflective electrodes RL3, respectively. The fourth reflective electrodes RL4 may be layers that reflect light from first through third light emitting layers EML1 through EML3. The fourth reflective electrodes RL4 may include a metal having high reflectivity to facilitate reflection of light. The fourth reflective electrodes RL4 may include or be made of aluminum (Al), a stacked structure (Ti/Al/Ti) of aluminum and titanium, a stacked structure (ITO/AI/ITO) of aluminum and indium tin oxide, an APC alloy which is an alloy of silver (Ag), palladium (Pd) and copper (Cu), or a stacked structure (ITO/APC/ITO) of an APC alloy and indium tin oxide, but embodiments of the disclosure are not limited thereto. In an embodiment, for example, A thickness of each of the fourth reflective electrodes RL4 may be about 850 Å.

A tenth interlayer insulating layer INS10 may be disposed on the ninth interlayer insulating layer INS9 and the fourth reflective electrodes RL4. In an embodiment, the tenth interlayer insulating layer INS10 may be a silicon oxide (SiOx)-based inorganic layer, but embodiments of the disclosure are not limited thereto.

Tenth vias VA10 may penetrate or be disposed through the tenth interlayer insulating layer INS10 and may be connected to the exposed fourth reflective electrodes RL4, respectively. The tenth vias VA10 may include or be made of at least one selected from copper (Cu), aluminum (Al), tungsten (W), molybdenum (Mo), chromium (Cr), gold (Au), titanium (Ti), nickel (Ni) and neodymium (Nd) or an alloy thereof. Due to the step layer STPL, a thickness of a tenth via VA10 in the first subpixel SP1 may be smaller than a thickness of a tenth via VA10 in each of the second subpixel SP2 and the third subpixel SP3. For example, the thickness of the tenth via VA10 in the first subpixel SP1 may be about 800 Å, and the thickness of the tenth via VA10 in each of the second subpixel SP2 and the third subpixel SP3 may be about 1200 Å.

The light emitting element layer EML may be disposed on the light emitting element backplane EBP. The light emitting element layer EML may include light emitting elements, each including a first electrode AND, an intermediate layer IL and a second electrode CAT, and a pixel defining layer PDL.

The first electrode AND of each of the light emitting elements may be disposed on the tenth interlayer insulating layer INS10 and may be connected to a tenth via VA10. The first electrode AND of each of the light emitting elements may be connected to the drain area DA or the source area SA of a pixel transistor PTR through a tenth via VA10, the first through fourth reflective electrodes RL1 through RL4, the first through ninth vias VA1 through VA9, the first through eighth metal layers ML1 through ML8, and a contact terminal CTE. The first electrode AND of each of the light emitting elements LE may include or be made of at least one selected from copper (Cu), aluminum (Al), tungsten (W), molybdenum (Mo), chromium (Cr), gold (Au), titanium (Ti), nickel (Ni) and neodymium (Nd) or an alloy thereof. In an embodiment, for example, the first electrode AND of each of the light emitting elements may be titanium nitride (TiN).

The pixel defining layer PDL may be disposed on a portion of the first electrode AND of each of the light emitting elements. The pixel defining layer PDL may cover edges of the first electrode AND of each of the light emitting elements. The pixel defining layer PDL defines first through third emission areas EA1 through EA3.

The first emission area EA1 may be defined as an area in the first subpixel SP1 where the first electrode AND, the intermediate layer IL, and the second electrode CAT are sequentially stacked to emit light. The second emission area EA2 may be defined as an area in the second subpixel SP2 where the first electrode AND, the intermediate layer IL, and the second electrode CAT are sequentially stacked to emit light. The third emission area EA3 may be defined as an area in the third subpixel SP3 where the first electrode AND, the intermediate layer IL, and the second electrode CAT are sequentially stacked to emit light.

The pixel defining layer PDL may include first through third pixel defining layers PDL1 through PDL3. The first pixel defining layer PDL1 may be disposed on or to cover the edges of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. In an embodiment, each of the first pixel defining layer PDL1, the second pixel defining layer PDL2, and the third pixel defining layer PDL3 may be a silicon oxide (SiOx)-based inorganic layer, but embodiments of the disclosure are not limited thereto. In an embodiment, for example, a thickness of the first pixel defining layer PDL1, a thickness of the second pixel defining layer PDL2, and a thickness of the third pixel defining layer PDL3 may each be about 500 Å.

The intermediate layer IL may include a first intermediate layer IL1, a second intermediate layer IL2, and a third intermediate layer IL3.

The intermediate layer IL may have a tandem structure including a plurality of intermediate layers IL1 through IL3 that emit different lights or emit lights in different wavelength ranges, respectively. In an embodiment, for example, the intermediate layer IL may include the first intermediate layer IL1 that emits light of a first color, the second intermediate layer IL2 that emits light of a third color, and the third intermediate layer IL3 that emits light of a second color. The first intermediate layer IL1, the second intermediate layer IL2, and the third intermediate layer IL3 may be sequentially stacked.

The first intermediate layer IL1 may have a structure in which a first hole transport layer, a first organic light emitting layer emitting light of the first color, and a first electron transport layer are sequentially stacked. The second intermediate layer IL2 may have a structure in which a second hole transport layer, a second organic light emitting layer emitting light of the third color, and a second electron transport layer are sequentially stacked. The third intermediate layer IL3 may have a structure in which a third hole transport layer, a third organic light emitting layer emitting light of the second color, and a third electron transport layer are sequentially stacked.

The intermediate layer IL may cover the first electrode AND in each opening of the pixel defining layer PDL and cover the pixel defining layer PDL between neighboring subpixels SP1 through SP3, but may be partially disconnected.

In an embodiment, where the intermediate layer IL is disconnected between adjacent subpixels SP1 through SP3, leakage current between the adjacent subpixels SP1 through SP3 can be effectively prevented, and a color interference phenomenon can be effectively prevented. The color interference phenomenon refers to, for example, a phenomenon in which while a blue subpixel emits light, a red subpixel adjacent to the blue subpixel is unintentionally turned on. The color interference phenomenon occurs due to the leakage current and may occur when the blue subpixel and the red subpixel having a large difference in pixel driving voltage are adjacent to each other. For example, the leakage current refers to a phenomenon in which while a driving current is supplied to the light emitting element LE of the blue subpixel to turn on the blue subpixel, a portion of the driving current is transmitted to the red subpixel through at least some conductive layers of the intermediate layer IL. If the leakage current occurs, the red subpixel may be unintentionally turned on while the blue subpixel is turned on.

The number of intermediate layers IL1 through IL3 emitting different lights is not limited to that illustrated in FIG. 5. In an embodiment, for example, the intermediate layer IL may include two intermediate layers. In such an embodiment, at least one selected from the two intermediate layers may be substantially the same as the first intermediate layer IL1, and the other intermediate layer may include a second hole transport layer, a second organic light emitting layer, a third organic light emitting layer, and a second electron transport layer. In such an embodiment, a charge generation layer may be disposed between the two intermediate layers to supply electrons to at least one selected from the two intermediate layers and to supply charges to the other intermediate layer.

In an embodiment, the first through third intermediate layers IL1 through IL3 may all be disposed in the first emission area EA1, the second emission area EA2, and the third emission area EA3 in FIG. 5, but embodiments of the disclosure are not limited thereto. In an embodiment, for example, the first intermediate layer IL1 may be disposed in the first emission area EA1 and may not be disposed in the second emission area EA2 and the third emission area EA3. In such an embodiment, the second intermediate layer IL2 may be disposed in the second emission area EA2 and may not be disposed in the first emission area EA1 and the third emission area EA3. In such an embodiment, the third intermediate layer IL3 may be disposed in the third emission area EA3 and may not be disposed in the first emission area EA1 and the second emission area EA2. In this case, first through third color filters CF1 through CF3 of the optical layer OPL may be omitted.

The second electrode CAT may be disposed on the third intermediate layer IL3. The second electrode CAT may be disposed on the third intermediate layer IL3 in each of a plurality of trenches TRC. The second electrode CAT may include or be made of a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. In an embodiment where the second electrode CAT is made of a semi-transmissive conductive material, the light output efficiency of each of the first through third subpixels SP1 through SP3 may be increased by a microcavity effect.

The encapsulation layer TFE may be disposed on the light emitting element layer EML. The encapsulation layer TFE may include one or more inorganic layers TFEL and TFE2 to prevent permeation of oxygen or moisture into the light emitting element layer EML. In addition, the encapsulation layer TFE may include at least one organic layer to protect the light emitting element layer EML from foreign substances such as dust. In an embodiment, for example, the encapsulation layer TFE may include a first encapsulating inorganic layer TFE1, an encapsulating organic layer TFE2, and a second encapsulating inorganic layer TFE3.

The first encapsulating inorganic layer TFE1 may be disposed on the second electrode CAT, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer in which one or more inorganic layers selected from silicon nitride (SiNx) layer, silicon oxynitride (SiON) layer, silicon oxide (SiOx), titanium oxide (TiOx) layer, and aluminum oxide (AlOx) layer are alternately stacked. The encapsulating organic layer TFE2 may be a monomer. Alternatively, the encapsulating organic layer TFE2 may be an organic layer made of or including an organic material such as acryl resin, epoxy resin, phenolic resin, polyamide resin, or polyimide resin.

An adhesive layer ADL may be a layer for bonding the encapsulation layer TFE and the optical layer OPL together. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1 through CF3, a plurality of lenses LNS, and a filling layer FIL. The color filters CF1 through CF3 may include the first through third color filters CF1 through CF3. The first through third color filters CF1 through CF3 may be disposed on the adhesive layer ADL.

The first color filter CF1 may overlap the first emission area EA1 of the first subpixel SP1. The first color filter CF1 may transmit light of the first color, that is, light in a blue wavelength band. The blue wavelength band may be about 370 nanometers (nm) to about 460 nm. Therefore, the first color filter CF1 may transmit light of the first color among light emitted from the first emission area EA1.

The second color filter CF2 may overlap the second emission area EA2 of the second subpixel SP2. The second color filter CF2 may transmit light of the second color, that is, light in a green wavelength band. The green wavelength band may be about 480 nm to about 560 nm. Therefore, the second color filter CF2 may transmit light of the second color among light emitted from the second emission area EA2.

The third color filter CF3 may overlap the third emission area EA3 of the third subpixel SP3. The third color filter CF3 may transmit light of the third color, that is, light in a red wavelength band. The red wavelength band may be about 600 to 750 nm. Therefore, the third color filter CF3 may transmit light of the third color among light emitted from the third emission area EA3.

The lenses LNS may be disposed on the first color filter CF1, the second color filter CF2, and the third color filter CF3, respectively. Each of the lenses LNS may be a structure for increasing the ratio of light directed to the front of the display device 10. Each of the lenses LNS may have an upwardly convex cross-sectional shape.

The filling layer FIL may be disposed on the lenses LNS. The filling layer FIL may have a predetermined refractive index so that light can travel in the third direction DR3 at an interface between the lenses LNS and the filling layer FIL. In addition, the filling layer FIL may be a planarization layer. The filling layer FIL may be an organic layer made of or including an organic material such as acryl resin, epoxy resin, phenolic resin, polyamide resin, or polyimide resin.

The cover layer CVL may be disposed on the filling layer FIL. The cover layer CVL may be a glass substrate or a polymer resin such as resin. In an embodiment where the cover layer CVL is a glass substrate, the cover layer CVL may be attached onto the filling layer FIL. In such an embodiment, the filling layer FIL may serve to bond the cover layer CVL. In an embodiment where the cover layer CVL is a glass substrate, the cover layer CVL may serve as an encapsulation substrate. In an embodiment where the cover layer CVL is a polymer resin such as resin, the cover layer CVL may be directly applied on the filling layer FIL.

The polarizer (not illustrated) may be disposed on a surface of the cover layer CVL. The polarizer may be a structure for preventing visibility reduction due to reflection of external light. The polarizer may include a linear polarizer and a phase retardation film. In an embodiment, for example, the phase retardation film may be a quarter-wave plate (24 plate), but embodiments of the disclosure are not limited thereto. If visibility due to reflection of external light is sufficiently improved by the first through third color filters CF1 through CF3, the polarizer may be omitted.

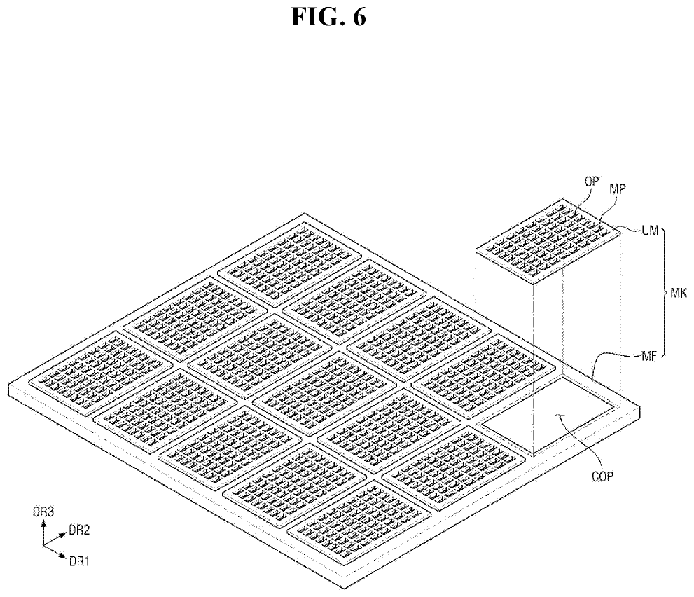

FIG. 6 is a perspective view of a mask according to an embodiment. FIG. 6 is a perspective view illustrating a state in which one unit mask UM is separated from a plurality of unit masks UM. The mask according to the embodiment illustrated in FIG. 6 may be used in a process of depositing at least a portion of the intermediate layer IL of the display panel 410 described with reference to FIG. 5. For example, the intermediate layer IL may be configured to emit light of a different color in each of the subpixels SP1 through SP3.

Referring to FIG. 6, a mask MK may include a mask frame MF and a plurality of unit masks UM. A plurality of cell openings COP formed through the mask frame MF along the thickness direction (e.g., third direction DR3) of the mask MK may be defined in the mask frame MF. The unit masks UM may be disposed to correspond to the cell openings COP, respectively. Each of the cell openings COP may correspond to one display panel 410. That is, one unit mask UM may be used in the process of depositing one display panel 410. In the disclosure, the term “unit mask UM” can be replaced with a term such as “mask unit UM”.

Each of the unit masks UM may include a mask body MP and a plurality of holes OP. The holes OP may be formed in the mask body MP and arranged in a matrix form. The holes OP may be defined through the unit masks UM along the thickness direction (e.g., third direction DR3) of the mask MK. The mask body MP of each of the unit masks UM may include a plurality of first mask grids extending along the first direction DR1 and spaced apart from each other. In addition, each of the unit masks UM may include a plurality of second mask grids extending along the second direction DR2 perpendicular to the first direction DR1 and spaced apart from each other. The first mask grids and the second mask grids may cross each other to define the holes OP. In the disclosure, the term “mask body MP” can be replaced with a term such as “mask frame” or “mask support.” In the disclosure, the term “mask grid” can be replaced with a term such as “mask rib.” In the disclosure, a combination of mask grids may be referred to as a term such as “mask membrane” or “membrane.” For example, the membrane may be a term that refers to a portion serving as a blocking portion in one unit mask.

The unit masks UM may be disposed on the mask frame MF. The unit masks UM and the cell openings COP may be disposed to correspond one-to-one to each other.

In an embodiment, the area of the mask body MP of each unit mask UM may be substantially the same as the area of each cell opening COP on a plane (e.g., a plane defined by the first direction DR1 and the second direction DR2).

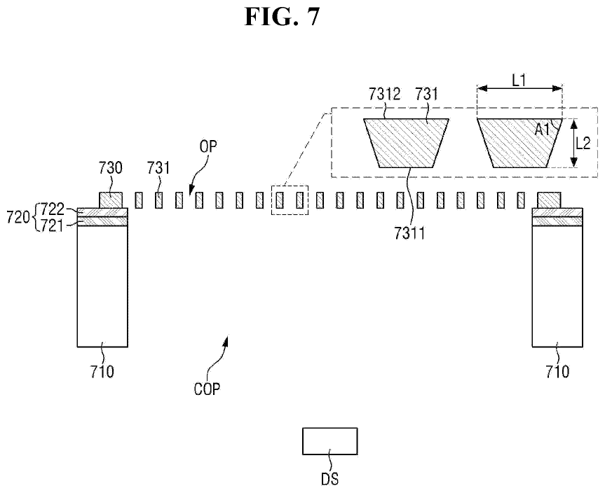

FIG. 7 is a schematic cross-sectional view of a mask according to an embodiment. FIG. 7 illustrates one of the unit masks UM.

Referring to FIG. 7, a mask MK according to an embodiment may be a silicon mask MK in which a mask membrane 730 (i.e., mask grids 731) is provided or formed on a silicon substrate 710 (i.e., a silicon wafer substrate). A fine metal mask (FMM) using an invar sheet has been widely used as a conventional deposition mask. However, the FMM has a problem in that its pixel position accuracy (PPA) performance is insufficient to manufacture high-resolution pixels. The mask MK according to an embodiment may increase alignment precision by forming mask membrane 730 on a silicon substrate 710 and may be used to manufacture an organic light emitting diode on silicon (OLEDoS) panel having high-resolution pixels of about 2000 pixels per inch (PPI) or higher.

The mask MK (i.e., the unit mask UM) according to an embodiment may include the silicon substrate 710 serving as a mask body, a seed metal layer 720 disposed on the silicon substrate 710, and the mask membrane 730 disposed on the seed metal layer 720 with a plurality of holes OP (i.e., mask openings) defined therethrough. The silicon substrate 710 may be provided with a cell opening COP defined therein to overlap the plurality of holes OP.

The seed metal layer 720 may include a first metal layer 721 including or containing titanium (Ti) and a second metal layer 722 disposed on the first metal layer 721 and including or containing titanium nitride (TIN). According to another embodiment, the seed metal layer 720 may be a single metal layer 721 including or containing titanium (Ti). According to another embodiment, the seed metal layer 720 may be a single metal layer 722 including titanium nitride (TIN). The material of the metal forming the seed metal layer 720 is not limited to titanium (Ti) and titanium nitride (TiN), and may be any metal as long as the seed metal layer 720 can be used in electroplating or electroforming method. In an embodiment, for example, the seed metal layer 720 may include copper (Cu).

Each of the mask grids 731 may include a plating layer formed through a damascene process, for example, using the electroplating or electroforming method.

Each of the mask grids 731 may have a reverse tapered shape having a width increasing as being from a back surface 7311 to an upper surface 7312. Here, the back surface 7311 of each of the mask grids 731 may be a surface facing a deposition source DS, and the upper surface 7312 of each of the mask grids 731 may be a surface facing a deposition target substrate, for example, the display panel 410 (i.e., a backplane substrate). The mask grids 731 according to an embodiment can reduce shadow defects due to the reverse tapered shape thereof. In an embodiment, for example, a taper angle of each mask grid 731 may be less than or equal to a deposition incidence angle which is an angle from the deposition source DS to a hole OP. In an embodiment, for example, the taper angle of each mask grid 731 may be designed or provided to be in a range of about 60 to about 90 degrees, a width L1 of a cross section of each mask grid 731 may be less than or equal to about 10 micrometers (μm), and a thickness L2 of the cross section of each mask grid 731 may be less than or equal to about 15 μm. The mask MK according to an embodiment can reduce shadow defects by reducing the thickness L2 of each mask grid 731 and providing each mask grid 731 to have a reverse tapered shape.

The mask grids 731 according to an embodiment may have a sagging problem because the thickness thereof is reduced to less than or equal to about 15 μm. In an embodiment, the mask grids 731 according to an embodiment include or are made of a magnetic metal. Therefore, sagging of the mask grids 731 can be effectively prevented using a magnetic member (not illustrated) inside a depositor (not illustrated), and alignment accuracy can be increased.

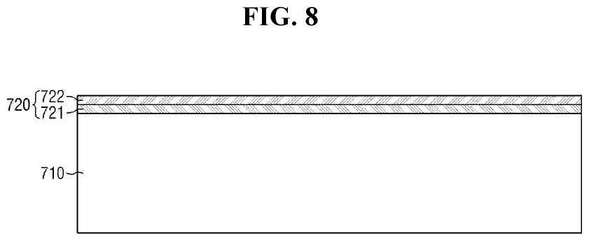

FIGS. 8 to 16 are cross-sectional views for explaining a method for manufacturing a mask MK according to an embodiment illustrated in FIG. 7.

Other processes in a method for manufacturing the mask MK related to the disclosure may be added before or after the manufacturing process of each mask MK described with reference to FIGS. 8 to 16. In addition, other processes in a manufacturing process of a mask MK known in the art may be added before or after the manufacturing process of each mask MK described with reference to FIGS. 8 to 16.

FIG. 8 shows a process of depositing the seed metal layer 720 on the silicon substrate 710 (hereinafter referred to as a first-first process). Referring to FIG. 8, the seed metal layer 720 may serve as a seed and a barrier metal to prevent the plating layer from penetrating into the silicon substrate 710 when performing electroplating. The seed metal layer 720 may be a single layer or a multilayer including or made of at least one conductive metal selected from titanium (Ti), titanium nitride (TiN), tantalum (Ta), tantalum nitride (TaN), nickel (Ni), gold (Au), and molybdenum (Mo).

The seed metal layer 720 may include a first metal layer 721 including or containing titanium (Ti) and a second metal layer 722 disposed on the first metal layer 721 and including or containing titanium nitride (TiN). According to another embodiment, the seed metal layer 720 may be a single metal layer 721 containing titanium (Ti), e.g., a titanium (Ti) single layer. According to another embodiment, the seed metal layer 720 may be a single metal layer 722 including titanium nitride (TiN), e.g., a titanium nitride (TiN) single layer. The material of the metal forming the seed metal layer 720 is not limited to titanium (Ti) and titanium nitride (TiN), and may be any metal as long as it is used in electroplating or electroforming method. In another embodiment, for example, the seed metal layer 720 may include copper (Cu).

The seed metal layer 720 may be formed through physical vapor deposition process such as sputtering, or a chemical vapor deposition process such as chemical vapor deposition (CVD) or plasma chemical vapor deposition (PECVD).

In the disclosure, the seed metal layer 720 may be referred to as the same term as “preliminary conductive layer.”

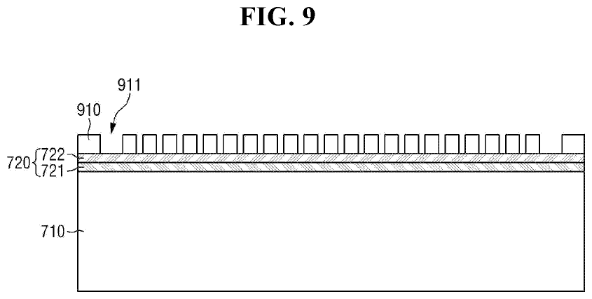

FIG. 9 shows a process of forming a first photoresist pattern 910 on the seed metal layer 720 (hereinafter referred to as a first-second process) as a process performed after the first-first process. Referring to FIG. 9, the first photoresist pattern 910 may be formed by applying a photoresist composition on the seed metal layer 720 and then patterning the photoresist composition. The cross section of the first photoresist pattern 910 may have a regular taper shape having a width decreasing as being away from the seed metal layer 720. In an embodiment, for example, the first photoresist pattern 910 may have a regular taper shape by patterning a positive photoresist composition. The cross section of the first photoresist pattern 910 has a regular taper shape so that the cross section of the plating layer which will become the mask membrane 730 has a reverse tapered shape.

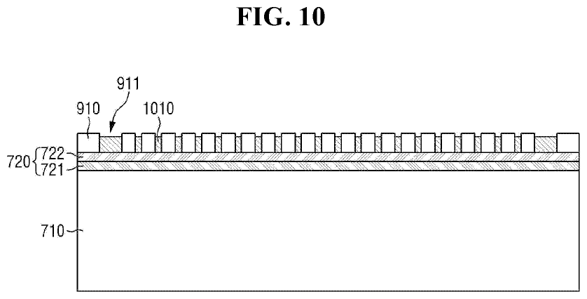

According to an embodiment, the first photoresist pattern 910 may be patterned to define a plurality of first openings 911. The plurality of first openings 911 may expose the seed metal layer 720 and form a space for growing a plating layer 1010 (see in FIG. 10).

FIG. 10 shows a process of growing the plating layer 1010 (hereinafter referred to as a first-third process) as a process performed after the first-second process. Referring to FIG. 10, the plating layer 1010 may include tungsten (W) or copper (Cu). The plating layer 1010 may be grown inside the plurality of first openings 911 of the first photoresist pattern 910. The height of the plating layer 1010 may be substantially the same as the height of the first photoresist pattern 910.

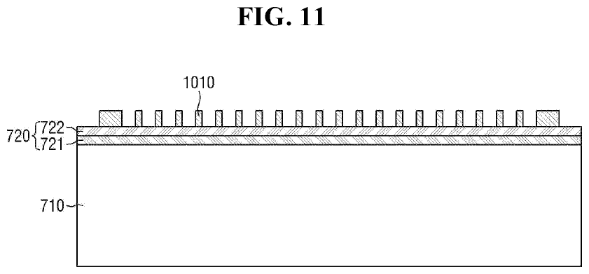

FIG. 11 shows a process of removing the first photoresist pattern 910 (hereinafter referred to as a first-fourth process) as a process performed after the first-third process. Referring to FIG. 11, the first photoresist pattern 910 may be removed after forming the plating layer 1010. The plating layer 1010 which remains after removing the first photoresist pattern 910 may serve as a mask membrane 730. That is, the plating layer 1010 which remains after removing the first photoresist pattern 910 may be mask grids 731 of the mask membrane 730.

According to an embodiment, the cross-section of each of the mask grids 731 of the mask membrane 730 may have a reverse tapered shape because the first photoresist pattern 910 that serves as a mold in which the plating layer 1010 is grown has a regular taper shape. In an embodiment, for example, the taper angle of the mask grid 731 may be designed or provided to be in a range of about 60 degrees to about 90 degrees, the width of the cross section of the mask grid 731 may be less than or equal to about 10 μm, and the thickness of the cross section of the mask grid 731 may be less than or equal to about 15 μm. The mask MK according to an embodiment can reduce shadow defects by reducing the thickness of the mask grid 731 and forming the mask grid 731 to have a reverse tapered shape.

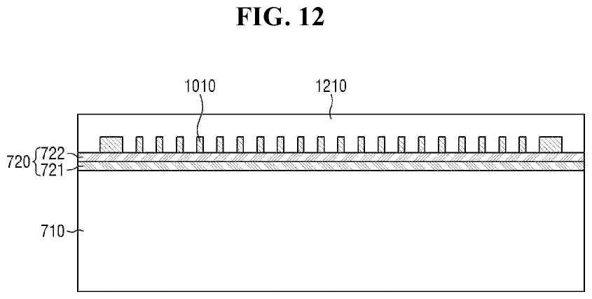

FIG. 12 shows a process of depositing a protection layer 1210 on the front surface of the mask membrane 730 (hereinafter referred to as a first-fifth process) as a process performed after the first-fourth process. Referring to FIG. 12, the protection layer 1210 may serve to prevent damage of the mask membrane 730 in the subsequent process.

The protection layer 1210 may include an inorganic layer including at least one selected from silicon nitride (SiNx), silicon oxynitride (SiON), silicon oxide (SiOx), titanium oxide (TiOx), and aluminum oxide (AlOx).

The protection layer 1210 may include an organic layer including at least one selected from acryl resin, epoxy resin, phenolic resin, polyamide resin, and polyimide resin.

The protection layer 1210 may be a multilayer which includes the inorganic layer described above and the organic layer described above.

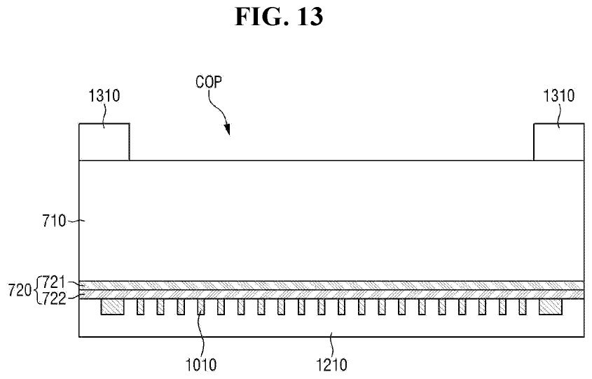

FIG. 13 shows a process of forming a second photoresist pattern 1310 on the back surface of a silicon substrate 710 (hereinafter referred to as a first-sixth process) as a process performed after the first-fifth process. Referring to FIG. 13, the second photoresist pattern 1310 may define second openings for defining a cell opening COP corresponding to each of the plurality of unit masks UM. In an embodiment, for example, each of the second openings may correspond to a corresponding one cell opening COP.

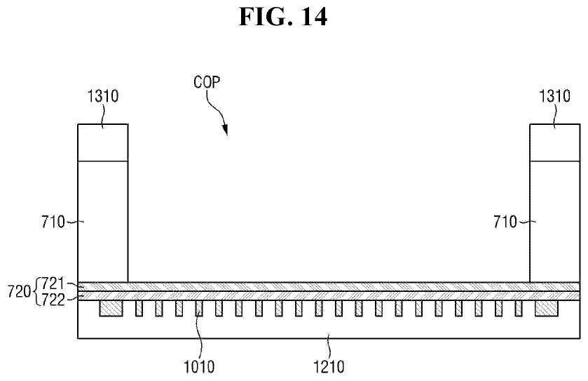

FIG. 14 shows a process of etching the back surface of the silicon substrate 710 (hereinafter referred to as a first-seventh process) as a process performed after the first-sixth process. Referring to FIG. 14, the silicon substrate 710 may be etched from the rear direction using the second photoresist pattern 1310. Here, the rear direction refers to a direction where a deposition source DS is positioned. The seed metal layer 720 may be exposed from the back surface by the etching of the silicon substrate 710. When etching the silicon substrate 710, the seed metal layer 720 may serve as an etch stopper.

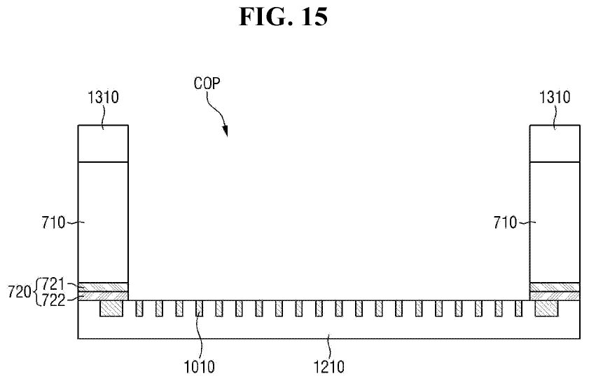

FIG. 15 shows a process of etching the seed metal layer 720 (hereinafter referred to as a first-eighth process) as a process performed after the first-seventh process. Referring to FIG. 15, a portion of the seed metal layer 720 corresponding to (or exposed through) the cell opening COP may be etched using the second photoresist pattern 1310 as the mask MK. Accordingly, the portion of the seed metal layer 720 overlapping the mask grid which configures the mask membrane 730 is removed, and the mask membrane 730 formed of the plating layer 1010 and the protection layer 1210 that covers the mask membrane 730 remain.

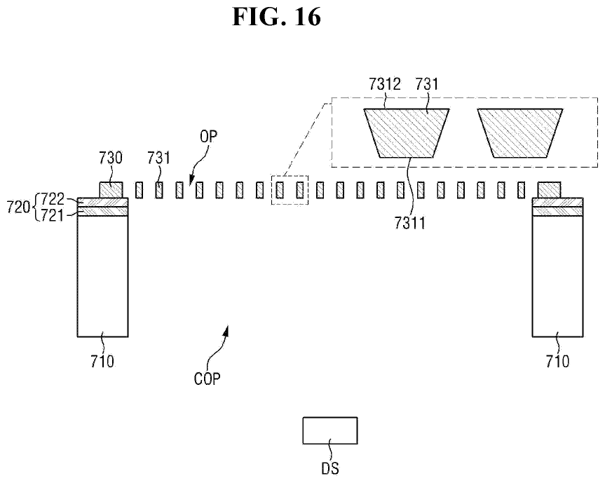

FIG. 16 shows a process of removing the second photoresist pattern 1310 and the protection layer 1210 (hereinafter referred to as a first-ninth process) as a process performed after the first-eighth process. Referring to FIG. 16, by removing the second photoresist pattern 1310 and the protection layer 1210, the manufacturing process of the mask MK according to an embodiment may be completed. Accordingly, the mask membrane 730 formed of the plating layer 1010 may be disposed in the mask MK, and the seed metal layer 720 and a portion of the plating layer disposed on the seed metal layer 720 may be disposed in the mask body except the cell opening COP.

The method for manufacturing the deposition mask MK according to embodiments can improve reliability by improving pixel position accuracy (PPA).

In addition, the method for manufacturing the deposition mask according to embodiments effectively prevent the mask from sagging by applying mask grids 731 (or mask ribs) to which a magnetic metal is applied. Accordingly, the alignment accuracy of the mask MK can be increased, and mura defects caused by the sagging of the mask MK can be prevented.

In addition, the method for manufacturing the deposition mask MK according to embodiments has improved rigidity or durability, thereby increasing the number of times the mask MK is used.

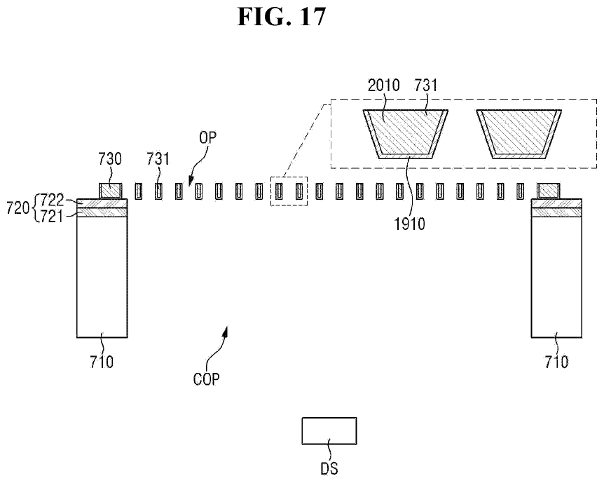

FIG. 17 is a schematic cross-sectional view of a mask MK according to an embodiment.

The embodiment of FIG. 17 is substantially the same as the embodiment of FIG. 16 except that the mask grid 731 is formed by using an inorganic material and a magnetic metal material. Hereinafter, any repetitive detailed description of the same or like elements and features thereof as those described above will be omitted, and only elements or features of the embodiment of FIG. 17 that is different from those of the embodiments of FIGS. 7 to 16 will be described.

Referring to FIG. 17, the mask MK (i.e., the unit mask UM) according to an embodiment may include a silicon substrate 710, which serves as a mask body, and a mask membrane 730 disposed on the silicon substrate 710 and providing a plurality of holes OP (i.e., mask openings). The silicon substrate 710 may be provided with a cell opening COP defined therein to overlap the plurality of holes OP.

The mask membrane 730 may include a plurality of mask grids 731, and each of the plurality of mask grids 731 may include a plating layer 2010 and a capping layer 1910 covering the plating layer 2010. The capping layer 1910 may be formed by a seed metal layer for electroplating. Here, the capping layer 1910 may be referred to as a “seed metal layer”.

Each of the mask grids 731 may have a reverse tapered shape having a width increasing as being away from a back surface 7311 to an upper surface 7312. Here, the back surface 7311 of each of the mask grids 731 may be a surface facing a deposition source DS, and the upper surface 7312 of each of the mask grids 731 may be a surface facing a deposition target substrate, for example, a display panel 410 (i.e., a backplane substrate). The mask grids 731 according to an embodiment can reduce shadow defects due to the reverse tapered shape thereof. In an embodiment, for example, a taper angle of each mask grid 731 may be less than or equal to a deposition incidence angle which is an angle from the deposition source DS to a hole OP. In an embodiment, for example, the taper angle of the mask grid 731 may be designed to be in a range of about 60 degrees to about 90 degrees, the width of the cross section of the mask grid 731 may be less than or equal to about 10 μm, and the thickness of the cross section of the mask grid 731 may be less than or equal to about 15 μm. The mask MK according to the embodiment can reduce shadow defects by reducing the thickness of the mask grid 731 and providing the mask grid 731 to have a reverse taper shape.

The mask grids 731 according to an embodiment may have a sagging problem because the thickness thereof is reduced to be less than or equal to about 15 μm. In an embodiment, the mask grids 731 according to an embodiment include or are made of a magnetic metal including the plating layer and the capping layer. Therefore, sagging of the mask grids 731 can be effectively prevented using a magnetic member (not illustrated) inside a depositor (not illustrated), and alignment accuracy can be increased.

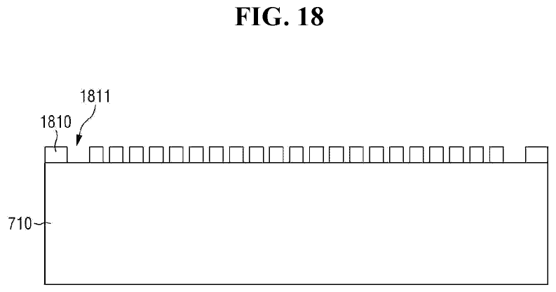

FIGS. 18 to 25 are cross-sectional views for explaining a method for manufacturing a mask MK according to an embodiment illustrated in FIG. 17.

Other processes of a manufacturing method of the mask MK related to the disclosure may be added before or after the manufacturing process of each mask MK described with reference to FIGS. 18 to 25. In addition, other processes of a manufacturing process of a mask MK known in the art may be added before or after the manufacturing process of each mask MK described with reference to FIGS. 18 to 25.

FIG. 18 shows a process of forming an inorganic layer pattern 1810 on the silicon substrate 710 (hereinafter referred to as a second-first step). Referring to FIG. 18, the inorganic layer pattern 1810 may include a silicon-based material. In an embodiment, for example, the inorganic layer pattern 1810 may include at least one selected from silicon (Si), silicon nitride (SiNx), silicon oxynitride (SiON), silicon oxide (SiOx), titanium oxide (TiOx), amorphous silicon (a-Si), and aluminum oxide (AlOx). The inorganic layer pattern 1810 may be formed by depositing an inorganic layer including or containing the material described above and then patterning the deposited inorganic layer.

The inorganic layer pattern 1810 defines a plurality of first openings 1811. The plurality of first openings 1811 may expose the silicon substrate 710 and form a space for growing a plating layer 2010.

The cross-section of the inorganic layer pattern disposed between adjacent first openings 1811 may be patterned to have a regular taper shape to allow the cross-section of the plating layer 2010, which will be the mask membrane 730, to have the reverse tapered shape.

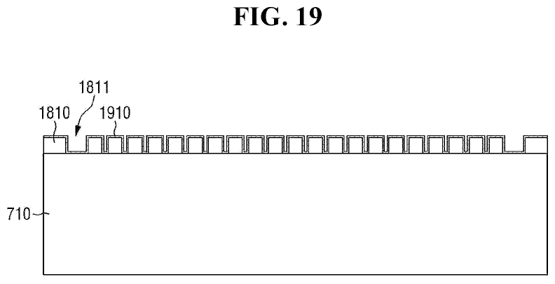

FIG. 19 shows a process of depositing a seed metal layer 1910 to cover the inorganic layer pattern 1810 and a plurality of first openings 1811 (hereinafter referred to as a second-second process) as a process performed after the second-first process. Referring to FIG. 19, the seed metal layer 1910 may serve as a barrier metal for preventing the plating layer 2010 from penetrating the inorganic layer pattern 1810 when performing electroplating and may serve as a seed. The seed metal layer 1910 may be a single layer or multilayer, each layer therein including at least one selected from conductive metals such as titanium (Ti), titanium nitride (TiN), tantalum (Ta), tantalum nitride (TaN), nickel (Ni), gold (Au), and molybdenum (Mo).

According to an embodiment, the seed metal layer 1910 may include a first metal layer including or containing titanium (Ti) and a second metal layer disposed on the first metal layer and including or containing titanium nitride (TiN). According to another embodiment, the seed metal layer 1910 may be a single metal layer including or containing titanium (Ti). According to still another embodiment, the seed metal layer 1910 may be a single metal layer including or containing titanium nitride (TiN). The material of the metal forming the seed metal layer 1910 is not limited to titanium (Ti) and titanium nitride (TiN), and may be any metal as long as it is used in electroplating or electroforming. In an embodiment, for example, the seed metal layer 1910 may include copper (Cu). In FIG. 19, the seed metal layer 1910 is shown as a single layer, but the seed metal layer 1910 may be a multilayer including a first metal layer including or containing titanium (Ti) and a second metal layer including or containing titanium nitride (TiN).

The seed metal layer 1910 may be formed through a physical vapor deposition process such as sputtering, or a chemical vapor deposition process such as chemical vapor deposition (CVD) and plasma chemical vapor deposition (PECVD). Such seed metal layer 1910 may serve as a capping layer covering the plating layer 2010.

In the disclosure, the seed metal layer 1910 may be referred to by terms such as “preliminary conductive layer.”

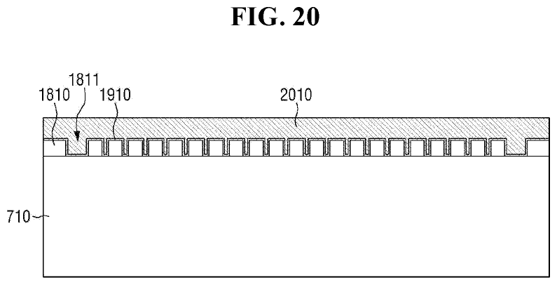

FIG. 20 shows a process of growing the plating layer 2010 (hereinafter referred to as a second-third process) as a process performed after second-second process. Referring to FIG. 20, the plating layer 2010 may include tungsten (W) or copper (Cu).

The plating layer 2010 may be grown to have a height higher than the inorganic layer pattern 1810. In an embodiment, for example, the second-third process of the plating process may be a process of growing the plating layer 2010 so that the height of the plating layer 2010 is higher than the height of the inorganic layer pattern 1810.

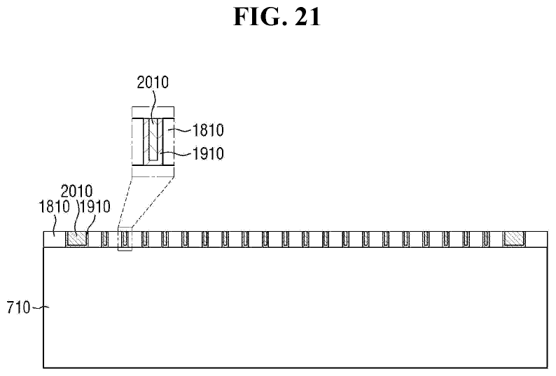

FIG. 21 shows a process of performing a chemical mechanical polishing pad (CMP) process (hereinafter referred to as a second-fourth process) as a process performed after second-third process. Referring to FIG. 21, a portion of the seed metal layer 1910 and a portion of the plating layer 2010 disposed on the inorganic layer pattern 1810 may be polished through the CMP process. Accordingly, the surface of the inorganic layer pattern 1810 and the surface of the plating layer 2010 may be generally uniform.

Portions of the plating layer 2010 which remains after the CMP process may become the mask grids 731 of the mask membrane 730. The portions of the plating layer 2010 which remains after the CMP process has a uniform thickness and may have a cross-sectional structure in a reverse tapered shape because the inorganic layer pattern 1810, which functioned as a mold in which the plating layer 2010 was grown, has a regular taper shape. In an embodiment, for example, the taper angle of the mask grid 731 may be designed to be in a range of about 60 degrees to about 90 degrees, the width of the cross section of the mask grid 731 may be less than or equal to about 10 μm, and the thickness of the cross section of the mask grid 731 may be less than or equal to about 15 μm. The mask MK according to an embodiment can reduce shadow defects by reducing the thickness of the mask grid 731 and having the mask grid 731 in a reverse tapered shape.

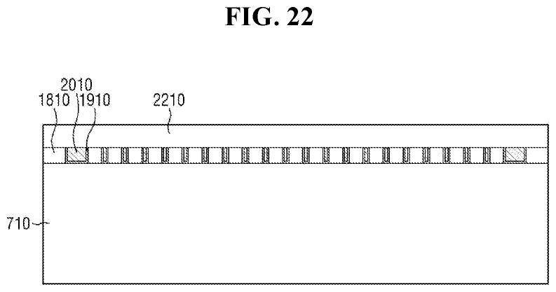

FIG. 22 shows a process of depositing a protection layer 2210 on the inorganic layer pattern 1810 (hereinafter referred to as a second-fifth process) as a process performed after second-fourth process. Referring to FIG. 22, the protection layer 2210 may serve to prevent damage of the mask membrane 730 in the subsequent process.

The protection layer 2210 may include an inorganic layer including at least one selected from silicon nitride (SiNx), silicon oxynitride (SiON), silicon oxide (SiOx), titanium oxide (TiOx), and aluminum oxide (AlOx).

The protection layer 2210 may include an organic layer including at least one selected from acryl resin, epoxy resin, phenolic resin, polyamide resin, and polyimide resin.

The protection layer 2210 may be a multilayer which includes the inorganic layer described above and the organic layer described above.

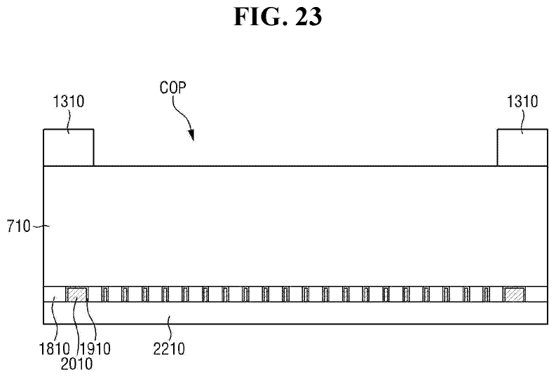

FIG. 23 shows a process of forming a photoresist pattern 1310 on the rear surface of the silicon substrate 710 (hereinafter referred to as a second-sixth process) as a process performed after second-fifth process. Referring to FIG. 23, the photoresist pattern 2310 may be provided with second openings for defining a plurality of cell openings COP corresponding to each of a plurality of unit masks UM. In an embodiment, for example, each of the second openings may correspond to one cell opening COP.

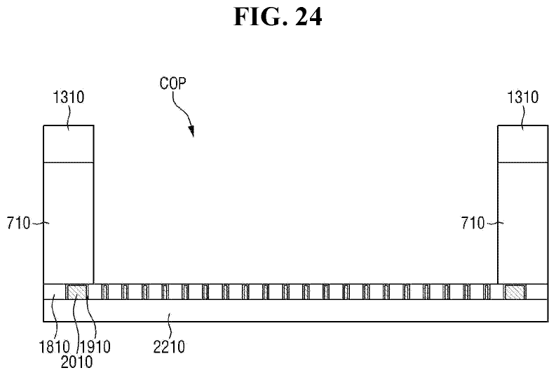

FIG. 24 shows a process of etching the back surface of the silicon substrate 710 (hereinafter referred to as a second-seventh process) as a process performed after the second-sixth process. Referring to FIG. 24, the silicon substrate 710 may be etched from the rear direction using the photoresist pattern 1310 as a mask MK. Here, the rear direction refers to a direction where a deposition source DS is positioned (e.g., the upper direction of FIG. 24). The seed metal layer 1910 may be exposed from the back surface by the etching of the silicon substrate 710. When etching the silicon substrate 710, the seed metal layer 1910 may serve as an etch stopper.

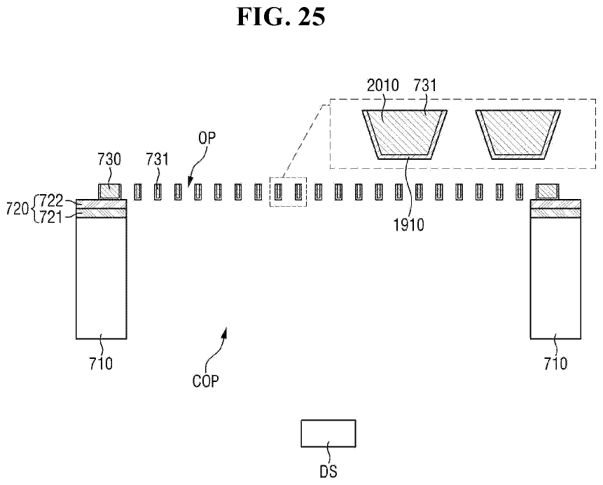

FIG. 25 shows a process of removing the inorganic layer pattern 1810 and the protection layer 2210 (hereinafter referred to as a second-eighth process) as a process performed after the second-seventh process. Referring to FIG. 25, by removing the inorganic layer pattern 1810 and the protection layer 2210, the manufacturing process of a mask MK according to an embodiment may be completed. Accordingly, the mask membrane 730 including the plating layer 2010 and a capping layer 1910 may be disposed in the cell opening in the mask MK.

The method for manufacturing the deposition mask MK according to embodiments can improve reliability by improving pixel position accuracy (PPA).

In addition, the method for manufacturing the deposition mask MK according to embodiments effectively prevent the mask from sagging by applying mask grids 731 (or mask ribs) to which a magnetic metal (i.e., plating layer 2010) is applied. Accordingly, the alignment accuracy of the mask MK can be increased, and mura defects caused by the sagging of the mask MK can be effectively prevented.

In addition, the method for manufacturing the deposition mask MK according to embodiments has improved rigidity or durability, thereby increasing the number of times the mask MK is used.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method for manufacturing a deposition mask, the method comprising:
depositing a seed metal layer on a front surface of a silicon substrate;
forming a first photoresist pattern defining a plurality of first openings on the seed metal layer;
growing a plating layer in the plurality of first openings of the first photoresist pattern;
forming a mask membrane by removing the first photoresist pattern and leaving the plating layer;
depositing a protection layer on a front surface of the seed metal layer to cover a front surface of the mask membrane;
forming a second photoresist pattern defining a plurality of cell opening corresponding to a plurality of unit masks, respectively, on a back surface of the silicon substrate;
exposing the seed metal layer by etching the back surface of the silicon substrate using the second photoresist pattern as a mask;
exposing a back surface of the mask membrane by etching the seed metal layer using the second photoresist pattern as a mask; and
removing the protection layer.

2. The method of claim 1,
wherein the seed metal layer includes a first metal layer including titanium (Ti) and a second metal layer disposed on the first metal layer and including titanium nitride (TiN).

3. The method of claim 1,
wherein the seed metal layer includes a single metal layer including titanium (Ti).

4. The method of claim 1,
wherein the seed metal layer includes a single metal layer including titanium nitride (TiN).

5. The method of claim 1,
wherein the mask membrane comprises a mask grid formed by the plating layer,
wherein a mask opening is defined between adjacently disposed mask grids to correspond to an area where the first photoresist pattern is removed.

6. The method of claim 5,
wherein a cross-section of the mask grid has a reverse tapered shape having a width increasing as being away from the back surface of the mask membrane toward the front surface of the mask membrane.

7. The method of claim 6,
wherein the mask opening has a width decreasing from the back surface of the mask membrane to the front surface of the mask membrane.

8. The method of claim 7,
wherein an opening of the mask has a first width at the back surface of the mask membrane and a second width smaller than the first width at the front surface of the mask membrane.

9. The method of claim 1,
wherein the plating layer includes tungsten (W).

10. The method of claim 1,
wherein the plating layer includes copper (Cu).

11. A method for manufacturing a deposition mask, the method comprising:
forming an inorganic layer pattern defining a plurality of first openings on a front surface of a silicon substrate;
depositing a seed metal layer on the front surface of the silicon substrate to cover the inorganic layer pattern and the plurality of first openings;
growing a plating layer on the seed metal layer in a way such that a height of the plating layer becomes higher than a height of the inorganic layer pattern;
polishing a portion of the seed metal layer and a portion of the plating layer disposed on the inorganic layer pattern by performing chemical mechanical polishing pad (CMP) process;
depositing a protection layer on the inorganic layer pattern;
forming a photoresist pattern defining a plurality of cell opening corresponding to a plurality of unit masks, respectively, on a back surface of the silicon substrate;
exposing the seed metal layer and the inorganic layer pattern by etching the back surface of the silicon substrate using the photoresist pattern as a mask; and
forming a mask membrane by removing the inorganic layer pattern and the protection layer,
wherein the mask membrane comprises a mask grid including the plating layer and the seed metal layer covering the plating layer.

12. The method of claim 11,
wherein the seed metal layer includes a first metal layer including titanium (Ti) and a second metal layer disposed on the first metal layer and including titanium nitride (TiN).

13. The method of claim 11,
wherein the seed metal layer includes a single metal layer including titanium (Ti).

14. The method of claim 11,
wherein the seed metal layer includes a single metal layer including titanium nitride (TiN).

15. The method of claim 11,
wherein the mask membrane comprises a mask grid including the plating layer and the seed metal layer covering the plating layer,
wherein a mask opening is defined between adjacently disposed mask grids to correspond to an area where the inorganic layer pattern is removed.

16. The method of claim 15,
wherein a cross-section of the mask grid has a reverse tapered shape having a width increasing as being away from the back surface of the mask membrane toward the front surface of the mask membrane.

17. The method of claim 16,
wherein the mask opening has a width decreasing as being away from the back surface of the mask membrane to the front surface of the mask membrane.

18. The method of claim 17,
wherein the opening of the mask has a first width at the back surface of the mask membrane and a second width smaller than the first width at the front surface of the mask membrane.

19. The method of claim 11,
wherein the plating layer includes tungsten (W).

20. The method of claim 11,
wherein the plating layer includes copper (Cu).
